(19) United States
(12) Patent Application Publication
(10) Pub. No.: US 2013/0158904 A1
(43) Pub. Date: Jun. 20, 2013

(54) APPARATUS AND METHOD FOR ASSESSING THE INTEGRITY OF ANALOG-DIGITAL CONVERTER

(71) Applicant: Lear Corporation, Southfield, MI (US)

(72) Inventors: Antoni Ferre Fabregas, Valls (ES); Jose Gabriel Fernandez Banares, Valls (ES); David Gamez Alari, Valls (ES)

(73) Assignee: Lear Corporation, Southfield, MI (US)

(21) Appl. No.: 13/707,107

(22) Filed: Dec. 6, 2012

Related U.S. Application Data
(60) Provisional application No. 61/576,454, filed on Dec. 16, 2011.

(51) Int. Cl. G01R 27/00; G06F 15/00

(52) U.S. Cl. CPC G01R 27/00; G06F 15/00
USPC 702/58

(57) ABSTRACT

An apparatus for determining integrity of an electronic device in a vehicle is provided. The apparatus comprises a controller operably coupled to a high voltage measuring circuit and to an analog-to-digital converter (ADC). The high voltage measuring circuit receives a high voltage signal and includes at least one stressed resistor for reducing the high voltage signal into a suitable voltage signal. The ADC performs a measurement with the suitable voltage that is indicative of the high voltage signal in a normal operation mode. The controller is configured to apply a calibrated voltage to the at least one stressed resistor in a calibration mode. The controller is further configured to calculate a resistance value of the at least one stressed resistor based on applying the calibrated voltage to the at least one stressed resistor to determine if the at least one stressed resistor is in a stressed state.

### CROSS-REFERENCE TO RELATED APPLICATIONS

This application claims the benefit of U.S. provisional Application No. 61/576,454 filed Dec. 16, 2011, the disclosure of which is incorporated in its entirety by reference herein.

### TECHNICAL FIELD

Embodiments disclosed herein generally relate to an apparatus and method for assessing the integrity of various electronics used in connection with an analog-to-digital converter (ADC) that measures high voltage.

### BACKGROUND

Drifts may occur overtime in connection with various components associated with an analog-to-digital converter (ADC). Such drifts may affect the accuracy of various readouts obtained by the ADC and generally require attention.

U.S. Pat. No. 6,445,315 to den Breejen provides measurement data that is collected by isolated ADCs in multiple channels that may be related. In such a scenario, data may be transmitted to a microcontroller or programmable logic device for centralized processing. Gain and offset of the ADCs in different channels, particularly their drift relative to one another, is an issue which requires attention. In particular, a pair of precision resistors is provided to calibrate the different channels. The ADCs may be factory calibrated and the ratio between the two precision resistors stored within the ADCs. The ADCs may later self-calibrate by comparing their relative gains to the stored resistor ratio. Gain of one of the ADCs may be adjusted relative to the other in order to maintain a relative gain calibration. Although absolute gain is not calibrated (as the resistors are isolated) for particular applications, only relative gain between the ADCs is relevant.

### SUMMARY

An apparatus for determining integrity of an electronic device in a vehicle is provided. The apparatus comprises a controller operably coupled to a high voltage measuring circuit and to an analog-to-digital converter (ADC). The high voltage measuring circuit receives a high voltage signal and includes at least one stressed resistor for reducing the high voltage signal into a suitable voltage signal. The ADC performs a measurement with the suitable voltage that is indicative of the high voltage signal in a normal operation mode. The controller is configured to apply a calibrated voltage to the at least one stressed resistor in a calibration mode. The controller is further configured to calculate a resistance value of the at least one stressed resistor based on applying the calibrated voltage to the at least one stressed resistor to determine if the at least one stressed resistor is in a stressed state.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompany drawings in which:

FIG. 1 depicts an apparatus for assessing the integrity of various electronics used in connection with an ADC in accordance to one embodiment;

FIG. 2 depicts an apparatus for assessing the integrity of various electronics used in connection with the ADC in accordance to another embodiment;

FIG. 3 depicts an apparatus for assessing the integrity of various electronics used in connection with the ADC in accordance to another embodiment;

FIG. 4 depicts an apparatus for assessing the integrity of various electronics used in connection with the ADC in accordance to another embodiment;

FIG. 5 depicts a method for determining when to enter into a calibration mode from a normal operation mode to assess the integrity of various electronics used in connection with the ADC in accordance to one embodiment; and

FIGS. 6A-6B depict a method for assessing the integrity of various electronics used in connection with the ADC in accordance to one embodiment.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

The embodiments of the present disclosure generally provide for a plurality of circuits or other electrical devices. All references to the circuits and other electrical devices and the functionality provided by each, are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microprocessors, integrated circuits, memory devices (e.g., FLASH, RAM, ROM, EPROM, EEPROM, or other suitable variants thereof) and software which co-act with one another to perform operation(s) disclosed herein.

The embodiments of the present disclosure generally provide an apparatus and method for assessing the integrity of various electronics used in connection with an ADC for various high voltage applications. Resistors, for example, may undergo a large amount of stress when placed in series with a high voltage input. In the event it is desired to measure the high voltage input with an ADC across a resistor(s), such resistors may age due to the large amount of power dissipation that they experience over time. This may cause the values of these resistors to change over time. This condition may also impact the ADC's ability to provide accurate high voltage readings over time. The embodiments provided herein may assess the integrity of electronics over time by operating in a calibration mode, periodically, in which various voltage measurements are ascertained to determine if these electronics have been overstressed (i.e., their respective values change) over time. The embodiments provided herein may provide a notification in the event various electronics exhibit an overstressed condition. These aspects and others will be described in more detail below.

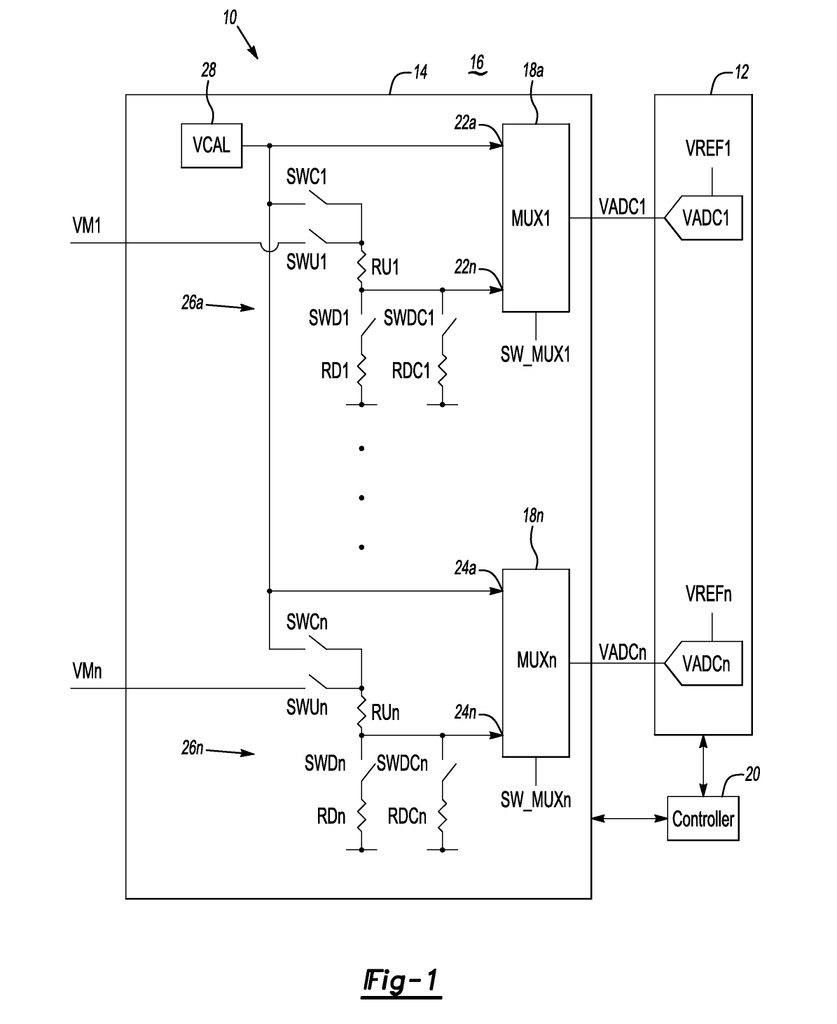

FIG. 1 depicts an apparatus 10 for assessing the integrity of various electronics used in connection with an ADC 12 in accordance to one embodiment. The apparatus 10 generally includes the ADC 12, a high voltage measuring circuit (“measuring circuit”) 14, and a controller 20 that are operably coupled to one another. The high voltage measuring circuit 14 includes a plurality of circuits 26a-26n that measure high voltages, VM1-VMn, respectively. Each circuit 26a-26n provides an analog signal indicative of such measured voltages VM1-VMn to respective A/D channels, ADC1-ADCn, of the ADC 12. Each ADC1-ADCn channel is arranged to receive a predetermined voltage VREF1-VREFn.

In one example, the apparatus 10 may be used in connection with a high voltage charging system for charging an electrical or hybrid vehicle 16. For example, the apparatus 10 may be configured to measure up to 500V for the purpose of providing multiple voltage measurements when used in connection with a charging or discharging operation of the vehicle 16. In another example, the apparatus 10 may be used in connection with a regenerative braking operation to measure voltages (i) such as a high voltage (e.g., 48V or with a minimum of 36V or greater) generated by an alternator, (ii) a battery input voltage and (iii) protection voltage across at least one switch generated as a result of regenerative braking In yet another example, the different measured voltages may correspond to additional high voltage applications such as battery charger output voltages, corresponding voltages used in connection with protective switches and the voltage across the battery. In general, these measured voltages are digitized using the ADC 12 in order to use the digital values in processing algorithms to control the performance of a high voltage system and to avoid misuse of the elements in the high voltage systems. For instance, it may be necessary to use the digital measured voltages in a battery charger to avoid overcharging of the battery or to measure the battery voltage to compute the state-of-charge (SOC) and a state-of-health (SOH) to avoid an under voltage condition (i.e. damages to the battery) due to excessive discharge. The above example may indicate why any number of the high voltages VMI-VMn is measured by the ADC12. It is recognized that the embodiments as disclosed herein may be used for any number of vehicle applications and those provided are not intended to be exhaustive.

The measuring circuit 14 includes a first plurality of resistors, RU1-RUn for receiving the high voltages, VM1-VMn, respectively. The measuring circuit 14 also includes a second plurality of resistors, RD1-RDn, which form voltage dividers with RU1-RUn. Such voltage dividers are formed to reduce the high voltages VM1-VMn into a suitable voltage level for receipt by the ADC 12. It is recognized that some ADCs are not capable of reaching high voltage measurements. In this case, the voltage dividers reduce the high voltage into a voltage that is suitable for processing by the ADC 12. The ADC 12 receives a suitable voltage from the voltage divider to perform a measurement of the high voltage input. The suitable voltages as received at the ADC 12 are generally indicative of the measured high voltage. The measuring circuit 14 also includes a third plurality of resistors RDC1-RDCn.

The measuring circuit 14 includes a first plurality of switches SWU1-SWUn and SWD1-SWDn, a second plurality of switches SWDC1-SWDCn, a third plurality of switches SWC1-SWCn and a plurality of multiplexer circuits 18a-18n. The multiplexer circuit 18a generally includes a first input 22a and a second input 24a. The multiplexer circuit 18n generally includes a first input 22n and a second input 24n. A plurality of switch selectors SW_MUX1-SW_MUXn are provided for activating inputs 22a-22n and 24a-24n of the multiplexer circuits 18a-18n respectively.

The apparatus 10 may be controlled to operate in a normal operation mode so that the apparatus 10 measures the high voltages VM1-VMn. The apparatus 10 may also be controlled to operate in a calibration mode so that the first plurality of resistors RU1-RUn are tested to determine if they have aged or been stressed due to the incoming high voltages VM1-VMn. Likewise in the calibration node the power supply 28 may also be tested to determine if VCAL has drifted over time. VCAL is generally a voltage reference that is used by the controller 20 to perform the calibration mode.

The normal operation mode will be explained in connection with circuit 26a in the apparatus 10. For purposes of brevity, the normal operation mode will not be described in connection to circuit 26n. For example, it is recognized that similar operations will be executed and will be equally applicable to circuit 26n in the apparatus 10 as that described below in connection with circuit 24. The only exception for circuit 26 is that various electronics: SWCn, SWUn, RUn, RDn, RDCn, SWDn, SWDCn, etc. are used in place of SWC1, SWU1, RU1, RD1, RDC1, SWD1, SWDC1, etc.

In the normal operation mode, the high voltage measuring circuit 14 provides the measured voltages VM1-VMn to the ADC 12. The controller 20 controls the switches SWC1 and SWDC to be open (i.e., OFF) while the switches SWU1 and SWD1 are closed (i.e., ON). The controller 20 also sets the switch selector SW_MUX1 to 1 so that the input 22n receives the measured voltage. As such, an input voltage to ADC1 (e.g. VADC) is:

VADC1=VM1*RD1/(RD1+RU1)=VM1/DIV1 (Eq. 1)

In general, DIV1 is a constant that is equal to (RDI+RUI)/RDI. The controller 20 stores the value DIV1 at the end of line and uses such a value to determine if recalibration is needed while the apparatus 10 is in the field. While in the normal operation mode, it can be shown that the resistor RU1 in the voltage divider network of Eq. 1 undergoes more stress than that of the resistor RD1. For example, assume that VM1 is in the range of 500V. If VREF1 as applied to ADC1 is equal to 1.2 V, then in order to maintain the input voltage to ADC1 (e.g., VADC1), the ratio between the resistors in the voltage divider network of resistance should be approximately 500 or as shown below:

RU1=500*RD1 (Eq. 2)

If, for example, RD1 is equal to 1 KOhm (i.e., 1000 Ohm), then RU1 is equal to 500 KOhms and DIV1=(RD1+RU1)/RD1=501.

In general, various voltages VREF1-VREFn are applied to ADC1-ADCn, respectively. It is recognized that any one of the voltages VREF1-VREFn may be modified or recalibrated over time in the event VCAL or RU1 drift over time. This will be explained in more detail below.

The increased amount of stress placed on RU1 can be shown again in the following manner. For example, in the event RD1=1 KOhm, RU1=500 KOhm and VM1=500V, then the power dissipation on RU1 is given by:

V_RU1=VM1*RU1/(RD1+RU1)=499 V (Eq. 3)

P_RU1=V_RU²/RU1=0.5 W (Eq. 4)

The power dissipation in RD1 can be shown by:

V_RD1=VM1*RD1/(RD1+RU1)=1 V (Eq. 5)

P_RD1=V_RD1²/RD1=0.001 W (Eq. 6)

As shown, the power dissipation across RD1 is significantly less than the power dissipation across RU1. This condition exhibits the amount of stress that RU1 (and RUn) may experience while in the operational mode. Because of the increased amount of stress being placed on RU1 and RUn, such resistors also operate at much higher temperatures than RD1 and RDn. These conditions may cause RU1 and RUn to age severely (e.g., their respective resistance nominal values may change over time) while RD1 and RDn may age at a much slower pace, if any at all.

It is recognized that RU1 and RUn may not be formed of a single resistor, but may instead be formed of several resistors that are in series with one another in order to reduce some degree of stress on these resistors. For example, RU1 and RUn may each be a resistor network of five resistors of 100 KOhms. While RU1 and RUn may be formed of a resistive network including a plurality of resistors, such a network may still exhibit large degrees of stress than RD1 and RDn. Thus, in view of the foregoing, it may be necessary to compensate for variations on RD1 and RDn. This may be accomplished by placing the apparatus 10 in a calibration mode.

Again, the operation of the calibration mode will be explained in connection with circuit 26a in the apparatus 10. For purposes of brevity, the calibration mode operation will not be described in connection to circuit 26n. For example, it is recognized that similar operations will be executed and will be equally applicable to circuit 26n in the apparatus 10 as that described below in connection with circuit 26a. The exception for circuit 26n is that various electronics: SWCn, SWUn, RUn, RDn, RDCn, SWDn, SWDCn, etc. are used in place of SWC1, SWU1, RU1, RD1, RDC1, SWD1, SWDC1, etc.

The measuring circuit 14 includes a power supply 28 that provides a predetermined voltage, VCAL to the measuring circuit 14 when the apparatus 10 is in the calibration mode. In the calibration mode, the apparatus 10 is not measuring the high voltages, VM1-VMn. The controller 20 controls the switches SWC1 and SWDC1 to close and the switches SWU1 and SWD1 to open. Resistor RDC1 is generally used in the calibration mode. This condition ensures that RDC1 is not used very often which further ensures that RDC1 will not drift or age over time. In addition, the controller 20 controls the switch selector SW_MUX1 to zero to activate the input 22a of the multiplexer 18a. As such, a first measured voltage Meas_1_A in ADC_1 is:

Meas_{—}1_A=VADC1=VCAL (Eq. 7a)

The controller 20 reads and stores Meas_1_A to determine if VCAL is still within an acceptable range.

The controller 20 then controls the switch selector SW_MUX1 to one to activate the input 22n. As such, a second measured voltage Meas_2_A in ADC_1 is:

Meas_{—}1_{—}B=VADC1=VCAL*RDC1/(RDC1+RU1) (Eq. 7b)

Through the use of equations 7a and 7b, the controller 20 determines the value of RU1 using the following equation:

RU1=RDC1*(Meas_{—}1_{—}A−Meas_{—}1_{—}B)/Meas_{—}1_{—}B (Eq. 8)

With the value of RU1 computed, the apparatus 10 determines if RU1 has changed over time and recalibrates the constant value of DIV1 if necessary. For example, the value of RU1 as calculated pursuant to Eq. 8 is compared to a stored value of RU1 to determine if it has changed, or aged overtime. In the event the calculated value of RU1 exceeds the stored value of RU1 in the calibration mode, then the controller 20 determines that the value of RU1 has changed over time.

As noted above in connection to Eq. 1, the controller 20 stores a constant value of DIV1. In the event RU1 is determined to have aged, then the controller 20 modifies (or recalibrates) the constant value of DIV1 to account for the aging of RU1. This recalibration of DIV1 (or any other constant values (e.g., DIV2-DIVn) compensates for the aging of the stressed resistor RU1 and enables the ADC 12 to provide the accurate values that are indicative of the measured voltages VM1-VMn while the apparatus 10 is in the field.

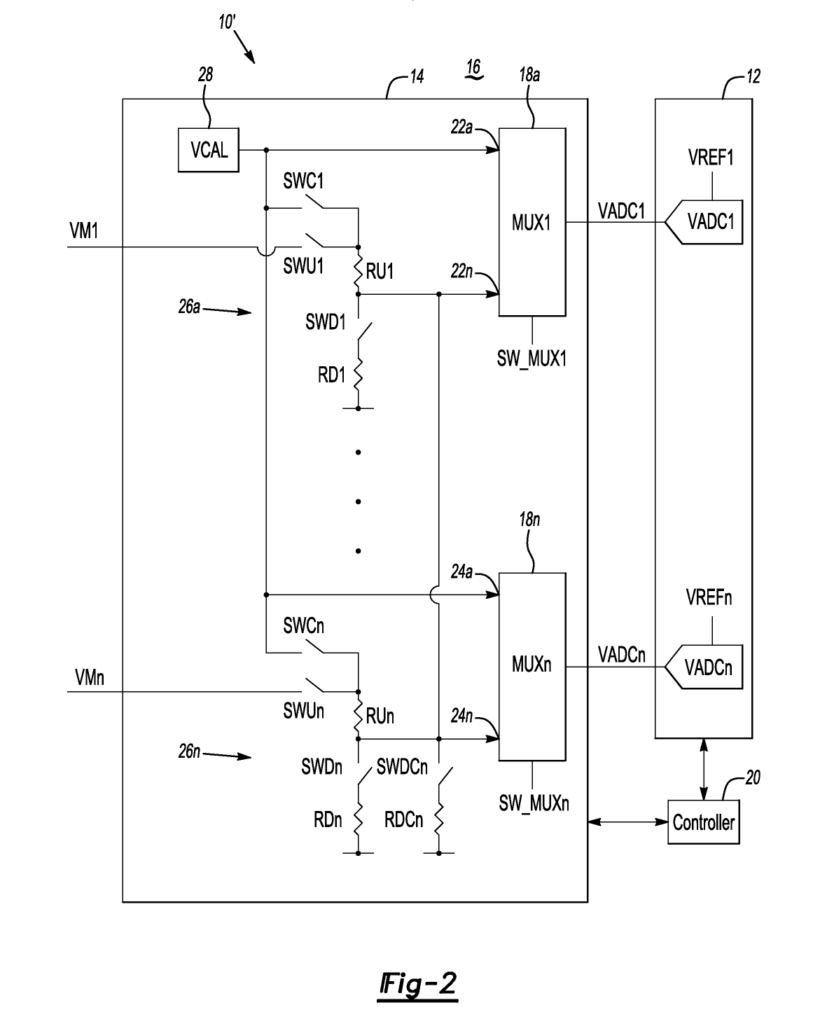

FIG. 2 depicts another apparatus 10′ for assessing the integrity of various electronics used in connection with the ADC 12 in accordance to one embodiment. The apparatus 10′ operates similarly to the apparatus 10 of FIG. 1. However, the apparatus 10′ may determine if RU1 and RUN has aged with a single switch SWDCn and a single resistor RDCn. In this implementation, the normal operation mode does not change and the switch SWDC1 and the resistor RDC1 may not be needed. Again, the switch SWDCn and the resistor RDCn are generally used in connection with the apparatus 10′ in the calibration mode.

In the calibration mode, the controller 20 controls the switches SWCn and SWDCn to close and the switches SWUn and SWDn to open. In addition, the controller 20 controls the switch selector SW_MUXn to zero to activate the inputs 22a and 24a. As such, the first measured voltage Meas_n_A in ADC_1 is:

Meas_n_A=VADCn=VCAL (Eq. 9a)

The controller 20 reads and stores the Meas_1_A to determine if VCAL is still in an acceptable range.

The controller 20 then controls the switch selector SW_MUXn to one. As such a second measured voltage Meas_n_B in ADCn is:

Meas_{—}n_{—}B=VADCn=VCAL*RDCn/(RDCn+RUn) (Eq. 9b)

Through the use of equations 9a and 9b, the controller 20 determines the value or RUn using the following equations. The controller 20 calculates RUn analogously to Equation 8.

RUn=RDC*(Meas_{—}n_{—}A−Meas_{—}n_{—}B)/Meas_{—}n_{—}B (Eq. 10)

With the value of RUn computed, the apparatus 10′ determines if it has changed over time and recalibrates the constant value DIV1 if necessary.

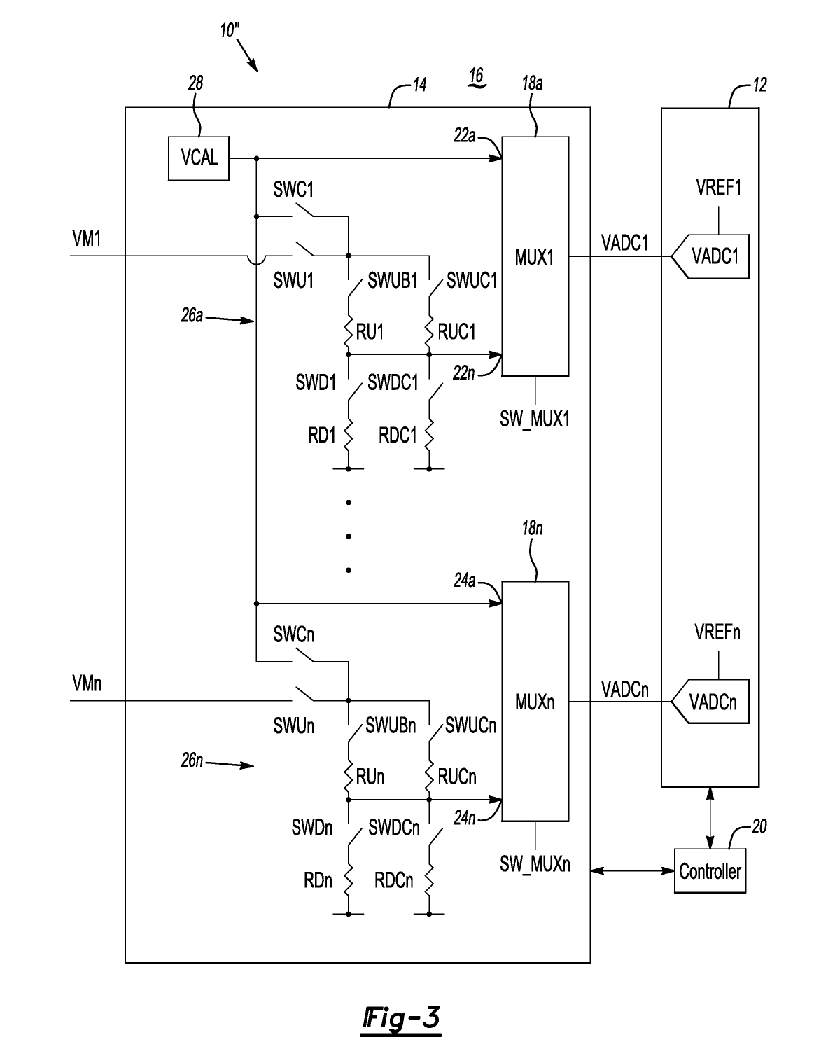

FIG. 3 depicts another apparatus 10″ for assessing the integrity of various electronics used in connection with the ADC 12 in accordance to another embodiment. The apparatus 10″ generally provides additional circuitry to compensate or monitor the aging of the resistors RU1 and RUn. For example, resistors RUC1-RUCn, switches SWUC1-SWUCn, and and SWUB1-SWUBn are provided.

The normal mode operation will now be described in connection with the circuit 26a of the apparatus 10″. The normal mode will not be described in connection to circuit 26n for purposes of brevity. For example, it is recognized that similar operations will be executed and will be equally applicable to circuit 26n in the apparatus 10″ as that described below in connection with circuit 26a with the exception of the terminology of the resistors and switches changing for the circuit 26n.

In the normal operation mode (e.g., when the apparatus 10″ is measuring VM1 for the first circuit 24), the controller 20 controls the switches SWC1, SWUC1, and SWDC1 to be open (i.e., OFF) and the switches SWU1, SWUB1, and SWD1 to be closed (i.e., ON). The controller 20 also sets the switch selector SW_MUX1 to 1 so that the input 22n receives the measured voltage VM1. As such, the input voltage to ADC_1 is:

VADC1=VM1*RD1/(RD1+RU1)=VM1/DIV1 (Eq. 11)

The calibration mode will now be described in connection with the circuit 26a of the apparatus 10″. The calibration mode will not be described in connection to circuit 26n for purposes of brevity. For example, it is recognized that similar operations will be executed and will be equally applicable to the circuit 26n in the apparatus 10″ as that described below in connection with circuit 26a with the exception of the terminology of the resistors and switches changing for the circuit 26n.

The controller 20 controls the switch selector SW_MUX1 to zero to activate the input 22a. As such, a first measured voltage Meas_1_A in ADC_1 is:

Meas_{—}1_A=VADC1=VCAL (Eq. 12)

The controller 20 reads and stores the Meas_1_A to determine if VCAL is still in an acceptable range.

The controller 20 then controls the switch selector SW_MUX1 to one. The controller 20 also controls the switches SWC1, SWUB1, SWDC1 to close (i.e., ON) and controls the switches SWU1, SWUC1, to SWD1 to open (i.e., OFF). Thus, the second measured voltage Meas_1_B in ADC_1 is:

Meas_{—}1_{—}B=VADC1=VCAL*RDC1/(RDC1+RU1) (Eq. 13a)

The controller 20 calculates VADC1 in view of Eq. 13. After this calculation, the controller 20 may determine whether the value of RU1 has drifted over time:

RU1=RDC1*(Meas_{—}1_{—}A−Meas_{—}1_{—}B)/Meas_{—}1_{—}B (Eq. 13b)

The controller 20 keeps the switch selector SW_MUX1 to one. The controller 20 then controls the switches SWC1, SWUC1, and SWD1 to close (i.e., ON) and controls the switches SWU1, SWUB1 and SWDC1 to open (i.e., OFF). Thus, a third measured voltage Meas_1_C in ADC_1 is:

Meas_{—}1_{—}C=VADC1=VCAL*RD1/(RD1+RUC1) (Eq. 13c)

The controller 20 calculates VADC in view of Eq. 14. After this calculation, the controller 20 determines whether the value of the resistor RD1 has drifted over time.

RD1=RUC1*Meas_{—}1_{—}C/(Meas_{—}1_{—}A−Meas_{—}1_{—}C) (Eq. 14)

Once the value for RU1 and RD1 is known, it is possible to recalibrate the constant value of DIV1 as noted above. In general, when a ratio between RU1 and RD1 is less than 10, such a difference may be indicative of a small power dissipation which corresponds to negligible aging in RD1 or RU1. However, in the event a ratio between RU1 and RD1 exceeds a predetermined ratio value, this condition may indicate that the aging of RU1 and/or RD1 may exceed a negligible level.

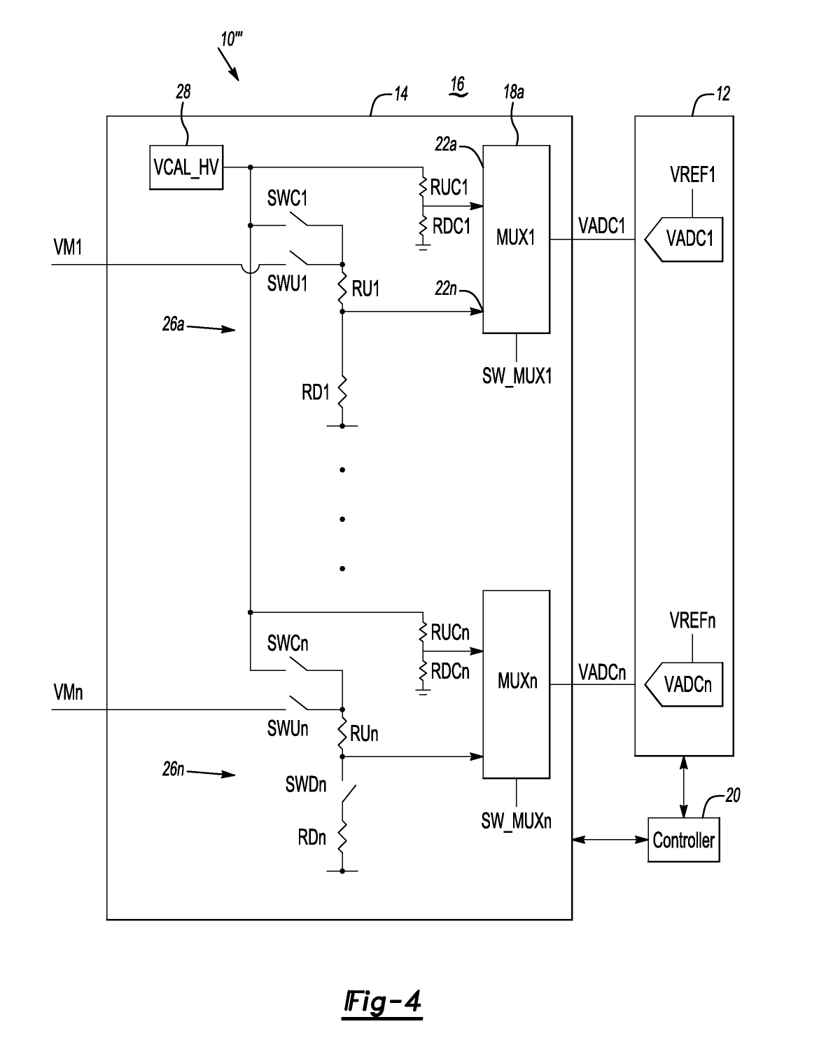

FIG. 4 depicts another apparatus 10′″ for assessing the integrity of various electronics used in connection with the ADC 12 in accordance to another embodiment. The apparatus 10′″ may be used in connection with a high voltage precision voltage reference, VCAL_HV. The high voltage precision voltage reference may provide for a simplified implementation.

The normal mode operation will be described in connection with the circuit 26a of the apparatus 10′″. The normal mode will not be described in connection to circuit 26n for purposes of brevity. For example, it is recognized that similar operations will be executed and will be equally applicable to circuit 26n in the apparatus 10′″ as that described below in connection with circuit 26a with the exception that the terminology of the resistors and switches changing for the circuit 26n.

In the normal operation mode (e.g., when the apparatus 10′″ is measuring VM1 for the circuit 26a), the controller 20 controls the switch SWC1 to be open (i.e., OFF) and controls the switch SWU1 to be closed (i.e., ON). The controller 20 also sets the switch selector SW_MUX1 to 1 so that the input 22n receives the measured voltage VM1. As such, the input voltage to ADC_1 is:

VADC1=VM1*RD1/(RD1+RU1)=VM1/DIV1 (Eq. 15)

The calibration mode will now be described in connection with the circuit 26a of the apparatus 10′″. The calibration mode will not be described in connection to circuit 26n for purposes of brevity. For example, it is recognized that similar operations will be executed and will be equally applicable to the circuit 26n in the apparatus 10′″ as that described below in connection with circuit 26a with the exception that the terminology of the resisters and switches changing for the circuit 26n.

The controller 20 (i) controls the switch selector SW_MUX1 to zero, (ii) controls the switch SWC1 to be closed (i.e., ON) and (iii) controls the switch SWU1 to be open (i.e., OFF) (e.g., the input 22a is activated). As such, the input voltage to ADC is:

VADC1=VCAL_HV*RDC1/(RDC1+RUC1) (Eq. 16)

The controller 20 then controls the switch selector SW_MUX1 to one to activate the input 22a. Thus, the input voltage of ADC is:

VADC1=VCAL_HV*RD1/(RDC+RU1) (Eq. 17)

After two measurements are performed, the controller 20 determines the values of RU1 and RD1 to determine if their values have changed over time. Once these values are known, it is possible to recalibrate DIV1.

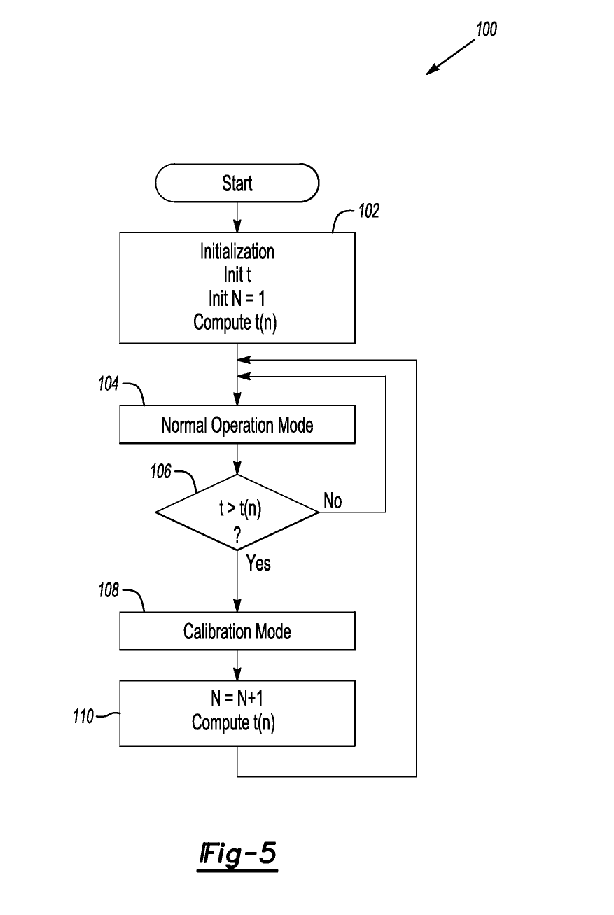

FIG. 5 depicts a method 100 for determining when to enter into a calibration mode from a normal operation mode to assess the integrity of various electronics used in connection with the ADC 12 in accordance to one embodiment.

In operation 102, the controller 20 is initialized such that time (t), and counter value N are initialized. In addition, the controller 20 stores a value t(n) which corresponds to a predetermined time. The predetermined time generally corresponds to a time in which the controller 20 exists from the normal operation mode and enters into the calibration mode for assessing the integrity of various electronics in the apparatus 10, 10′, 10″, and 10′″ as set forth above. In one example, the predetermined time t(n) may correspond to equispaced time instants, following equation t(n)=n·T, where T is a constant or to non-equispaced time instants following an event, such as every engine start up or when the engine is powering down, or to specific time instants computed by modeling the variation of the voltage references and/or the resistors as set forth in co-pending U.S. application Ser. No. 13/679,370 filed on Nov. 16, 2012 which is hereby incorporated by reference in its entirety.

In operation 104, the controller 20 operates in the normal operation mode. As noted above, the apparatus 10, 10′, 10″, and 10′″ may perform the operation of measuring high voltages to provide a vehicle related operation. The controller 20 may increase the time (t) while the apparatus 10, 10′, 10″, and 10′″ operate in the normal mode. It is recognized that time (t) may be increased over multiple normal mode operations. For example, time (t) may elapse or run over numerous uses of the apparatus 10, 10′, 10″, and 10′″ while functioning in the normal operating mode.

In operation 106, the controller 20 may compare a current time (t) to the predetermined time t(n). For example, the controller 20 may compare the elapsed time, or overall time the apparatus 10, 10′, 10″, and 10′″ has functioned in the normal operating mode at a given point to the predetermined time t(n) to determine if the time (t) exceeds t(n). This comparison may be performed, for example, at every engine start up or when the engine is powering down. The vehicle operation that triggers the comparison of time (t) to the predetermined time t(n) may vary based on the desired criteria of a particular implementation.

If the time (t) exceeds the predetermined time t(n), then the method 100 moves to operation 108. If not, then the method 100 moves back to operation 104.

In operation 108, the controller 20 controls the apparatus 10, 10′, 10″, and 10′″ to move from the normal operation mode to the calibration mode.

In operation 110, the controller 20 increments the counter value, N by one and moves back to operation 104. The counter N stores the number of calibrations completed. Thus, it is possible to determine the number of times that the 10, 10′, 10″, and 10′″ has been calibrated and, after a certain number of recalibrations, provide a warning or stop performing the recalibrations since the apparatus 10, 10′, 10″, and 10′″ may have exceeded its expected operational life.

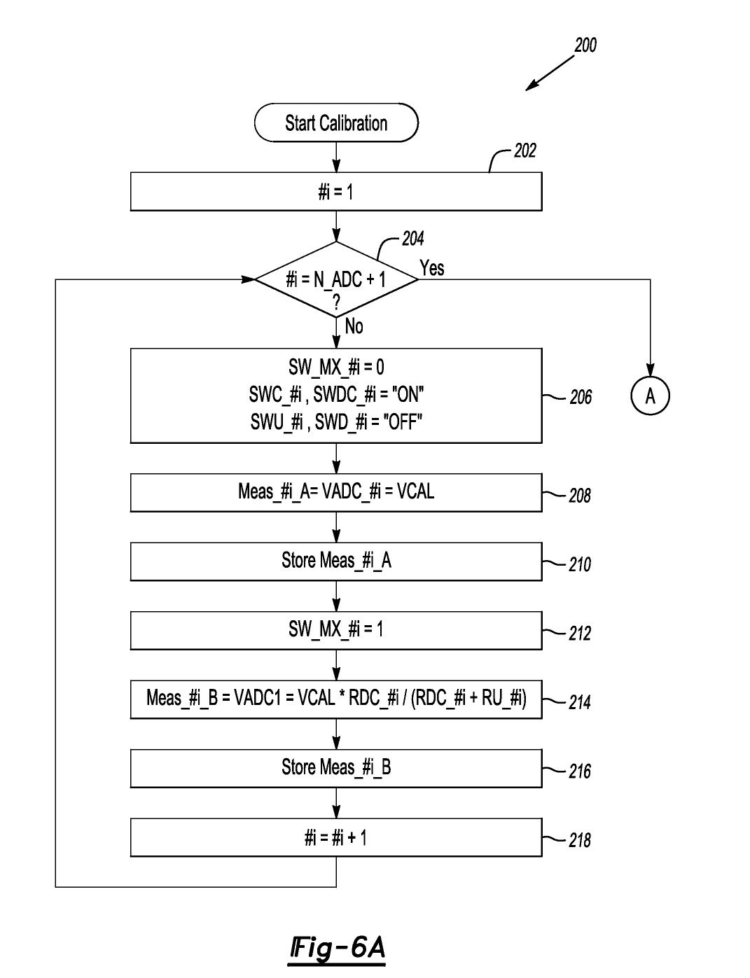

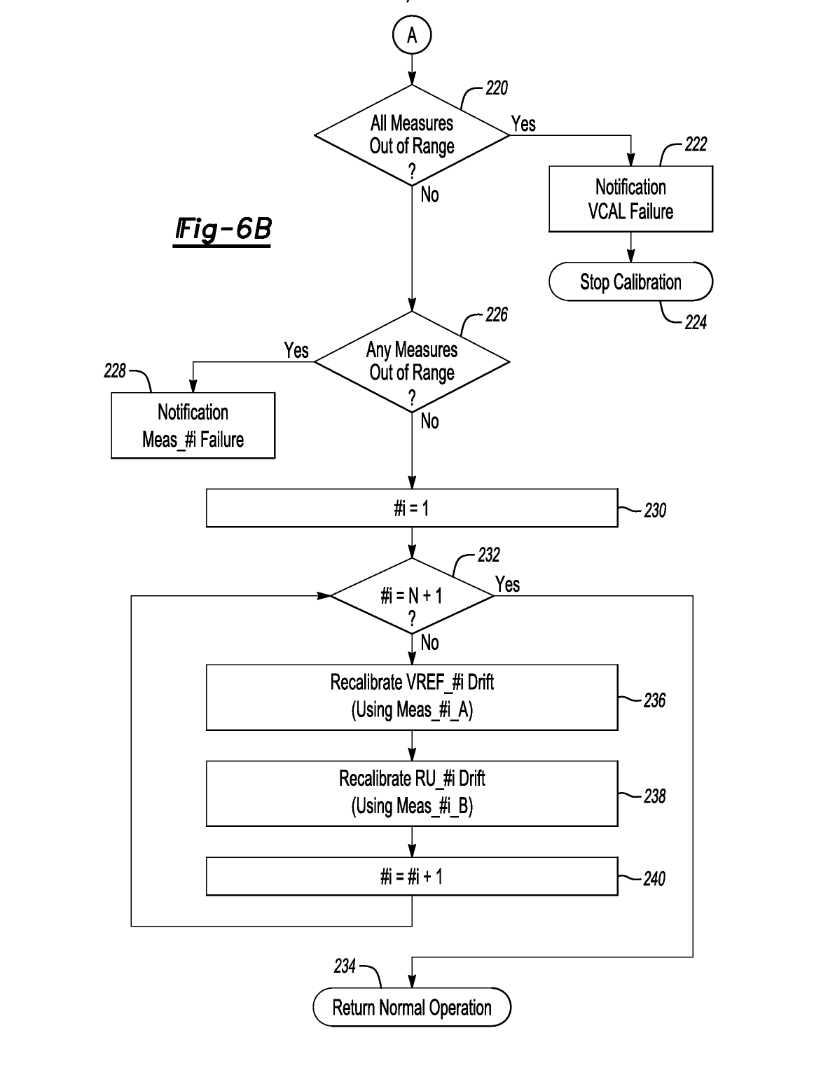

FIGS. 6A-6B depict a method 200 for assessing the integrity of various electronics used in connection with the ADC 12 in accordance to one embodiment. The method will be described as noted in connection to the circuit 26a of the apparatus 10, 10′, 10″, and 10′″ for purposes of brevity. It is recognized that the method 200 equally applies to the circuit 26n.

In operation 202, the controller 22 sets a count value, i equal to 1. The count value i generally corresponds to the respective circuit 26a, 26b, 26c, . . . 26n that is being placed in the calibration mode. For example, in reference to the apparatus 10 as shown in connection with FIG. 1, when i=1, this condition designates that the circuit 26a will be placed in the calibration mode and so on as the count value is incremented.

In operation 204, the controller 20 compares the count value, i to the total number of different ADCs (e.g. ADC_1-ADC_N (see FIGS. 1-4)) in (e.g. N_ADC) in the apparatus 10, 10′, 10″, 10′″ to determine if the count value is higher than the total number of different ADCs in the apparatus 10, 10′, 10″, 10′″. If the count value i is equal to N_ADC+1, then this condition generally indicates that all of the circuits (26a, 26n) that are operably coupled to the ADC 12 have been placed in the calibration mode and corresponding measurements of VADC1-VADCn have been obtained. If this condition is met, then the method 200 proceeds to operation 220. If not, then this condition generally indicates that a next circuit (e.g., 26b, 26c, . . . 26n) is to be placed in the calibration mode for purposes of measuring VADCb-VADCn. If the count value i is not equal to the total number of different ADCs (e.g. N_ADC), then the method 200 moves to operation 206.

In operation 206, the controller 20 (i) initializes the selector switch SW_MX_i=0, closes the switches SWCi and SWDCi, and opens the switches SWUi and SWDi to place the corresponding circuit 26a-26n in the calibration mode.

In operation 208, the controller 20 determines the first measured voltage Meas_1_A (e.g. see Eq. 7a), which in this case is equal to VCALi and VADCi.

In operation 210, the controller 20 stores the first measured voltage Meas_1_A.

In operation 212, the controller 20 sets the selector switch SW_MX_i to 1.

In operation 214, the controller 20 determines the second measured voltage Meas_1_B as set for below (see also Eq. 7b for example) while the selector switch SW_MX_i is set to 1. In this case, VADCi is measured according to:

VADCi=VCAL*RDCi/(RDCi+RUi) (Eq. 18)

In operation 216, the controller 20 stores the second measured voltage MEAS_1_B.

In operation 218, the controller 20 increments the count value, i by one and returns to operation 204.

In operation 220, the controller 20 determines whether all of the first measured voltages (e.g., MEAS_1_i) and all of the second measured voltages (e.g., MEAS_2_i) exceed a first predetermined range and a second predetermined range, respectively. For example, the controller 20 determines whether all of the first measure voltages (e.g., MEAS_1_i) and the all of the second measured voltages (e.g., MEAS_2_i) exceed the first predetermined range and the second predetermined range, respectively, for all circuits 26a-26n. If this condition is true, then the method 200 moves to operation 222. If not, then the method 200 moves to operation 226.

In operation 222, the controller 20 determines that the power supply 28 that generally provides VCAL is experiencing a failure and provides an electronic notification to a user that there is a failure. If VCAL is experiencing a failure, this condition would generally lead to all of the first measured voltages MEAS_1_i and all of the second measured voltages MEAS_2_i providing values that were out of range.

In operation 224, the controller 20 ceases performing the calibration mode since the power supply 28 that provides VCAL is experiencing a failure.

In operation 226, the controller 20 determines whether at least one of the second measured voltages (e.g., MEAS_2_i) exceed the second predetermined range for any of the circuits 26a-26n. If this condition is true, then the method 200 moves to operation 228. If not, then the method 200 moves to operation 230.

In operation 228, the controller 20 provides an electronic notification that a resistor in the apparatus 10, 10′, 10″, and 10′″ has aged and is no longer in range.

In operation 230, the controller 20 sets the count value, i equal to 1 for the purpose of recalibrating any VREF1 in the event VCAL is detected to exhibit a drift condition (see operation 236) for the circuit 26a. The controller 20 sets the count value, i equal to 1 for the purpose of recalibrating RU1 in the event RU1 is detected to exhibit a drift condition (see operation 238) for the circuit 26a.

In operation 232, the controller 20 compares the count value, i to the total number of different ADCs (e.g., N_ADC) in the apparatus 10, 10′, 10″, and 10′″ to determine if the count value is higher than the total number of different ADCs (N_ADC) in the apparatus 10, 10′, 10″, and 10′″. If the count value i is equal to N_ADC+1, then this condition generally indicates no recalibration is necessary. In this case, and the method 200 then proceeds to operation 234. If not, then this condition generally indicates that recalibration may be needed and will be performed in connection with operations 236 and/or 238 as needed for a particular circuit 26a-26n. If the count value i is not equal to the predetermined value, then the method 200 moves to operation 236 and so on.

In operation 236, the controller 20 recalibrates any one or more of VREFi for a given ADC_1-ADC_n using the first measurement of VADC1.

The calibration is as follows. The ADC 12 generates a digital output code for a sensor input V_{IN} according to the following equation:

output=V_{IN}*(2ⁿ/V_{REF})

where “output” is the digital output code in decimal form and “n” is the number of bits of resolution of the ADC. The apparatus 10, 10′, 10″, and 10′″ is calibrated at end of line, after manufacture, and the output code obtained is stored in memory and this value is used to correct the following measurements as disclosed herein. When calibration is complete, the stored code is compared with the measured output code and the value stored in memory is modified accordingly.

In operation 238, the controller 20 recalibrates any one or more of RU1-RUn using the second measurement of VADC1.

The calibration is performed by modifying the constant value of DIV1 as explained above. Considering ADC1 and the first and the second measured voltages (e.g., Meas_1_A, and Meas_1_B), the controller 20 determines the value of RU1 using the following equation:

RU1=RDC1*(Meas_{—}1_{—}A−Meas_{—}1_{—}B)/Meas_{—}1_{—}B

With the value of RU1 computed, the apparatus 10, 10′, 10″, 10′″ determines if it has changed over time and recalibrates the constant value of DIV1.

In operation 240, the controller 20 increases the count value, i to 2 so that operations 136 and 138 may be re-executed again for circuit 26b and so on in the event recalibration is needed.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. An apparatus for determining integrity of an electronic device in a vehicle, the apparatus comprising:
a controller operably coupled to a high voltage measuring circuit and to an analog-to-digital converter (ADC), the high voltage measuring circuit for receiving a high voltage signal and including at least one stressed resistor for reducing the high voltage signal into a suitable voltage signal to provide to the ADC to perform a measurement thereof that is indicative of the high voltage signal in a normal operation mode, the controller being configured to:
apply a calibrated voltage to the at least one stressed resistor in a calibration mode; and
calculate a resistance value of the at least one stressed resistor based on applying the calibrated voltage to the at least one stressed resistor to determine if the at least one stressed resistor is in a stressed state.

2. The apparatus of claim 1 wherein the controller is further configured to measure the calibrated voltage to generate a first measured voltage prior to applying the calibrated voltage to the at least one stressed resistor.

3. The apparatus of claim 2 wherein the controller is further configured to control at least one switch for preventing the measuring circuit to receive the high voltage signal and for enabling the measuring circuit to receive the calibrated voltage in the calibrated mode.

4. The apparatus of claim 2 wherein the controller is further configured to apply the calibrated voltage to the at least one stressed resistor to generate a second measured voltage.

5. The apparatus of claim 4 wherein the controller is further configured to calculate the resistance value of the at least one stressed resistor based on the second measured voltage.

6. The apparatus of claim 1 wherein the controller is further configured to control at least one switch for controlling the apparatus to move from the normal operating mode into the calibration mode.

7. The apparatus of claim 1 wherein the at least one stressed resistor cooperates with a first resistor to provide a voltage divider for reducing the high voltage signal into the suitable voltage signal to perform the measurement in the normal operation mode.

8. The apparatus of claim 1 wherein the high voltage signal is greater than 36 volts.

9. The apparatus of claim 1 wherein the high voltage signal is greater than 400 volts.

10. An apparatus for determining integrity of an electrical device in a vehicle, the apparatus comprising:
a high voltage measuring circuit for receiving a high voltage signal and including at least one stressed resistor for reducing the high voltage signal into a suitable voltage signal;
an analog-to-digital converter (ADC) for receiving the suitable voltage level to perform a measurement thereof that is indicative of the high voltage signal in a normal operation mode;
a controller configured to:
apply a calibrated voltage to the at least one stressed resistor in a calibration mode; and
calculate a resistance value of the at least one stressed resistor based on applying the calibrated voltage to the at least one stressed resistor to determine if the at least one stressed resistor is in a stressed state.

11. The apparatus of claim 10 wherein the controller is further configured to measure the calibrated voltage to generate a first measured voltage prior to applying the calibrated voltage to the at least one stressed resistor.

12. The apparatus of claim 11 wherein the controller is further configured to control at least one switch for preventing the measuring circuit to receive the high voltage signal and for enabling the measuring circuit to receive the calibrated voltage in the calibrated mode.

13. The apparatus of claim 11 wherein the controller is further configured to apply the calibrated voltage to the at least one stressed resistor to generate a second measured voltage.

14. The apparatus of claim 13 wherein the controller is further configured to calculate the resistance value of the at least one stressed resistor based on the second measured voltage.

15. The apparatus of claim 10 wherein the controller is further configured to control at least one switch for controlling the apparatus to move from the normal operating mode into the calibration mode.

16. The apparatus of claim 10 wherein the at least one stressed resistor cooperates with a first resistor to provide a voltage divider for reducing the high voltage signal into the suitable voltage signal to perform the measurement in the normal operation mode.

17. The apparatus of claim 10 wherein the high voltage signal is greater than 36 volts.

18. The apparatus of claim 10 wherein the high voltage signal is greater than 400 volts.

19. A method for determining integrity of an electrical device in a vehicle, the method comprising:
receiving a high voltage signal;
reducing the high voltage signal via at least one stressed resistor to provide a suitable voltage signal;
digitally converting the suitable voltage level to perform a measurement that is indicative of the high voltage signal in a normal operation mode;
applying a calibrated voltage to the at least one stressed resistor in a calibration mode; and
calculating a resistance value of the at least one stressed resistor based on applying the calibrated voltage to the at least one stressed resistor to determine whether the at least one stressed resistor is in stressed state.

20. The method of claim 19 further comprising measuring the calibrated voltage to generate a first measured voltage prior to applying the calibrated voltage to the at least one stressed resistor.
